(19) United States
(12) Patent Application Publication
(10) Pub. No.: US 2010/0149672 A1
(43) Pub. Date: Jun. 17, 2010

(54) OPTICAL FILTER AND MANUFACTURING METHOD THEREOF

(76) Inventors: Jin-Young Lee, Suwon-si (KR); Sung-Yong Lee, Suwon-si (KR); Jae-Hyung Kim, Suwon-si (KR)

Correspondence Address: CHRISTIE, PARKER & HALE, LLP, PO BOX 7068, PASADENA, CA, 91109-7068, US

(21) Appl. No.: 12/625,549

(22) Filed: Nov. 24, 2009

(30) Foreign Application Priority Data
Dec. 12, 2008 (KR) 10-2008-0126376

(51) Int. Cl. G02B 5/22; G03F 7/20

(52) U.S. Cl. 359/885; 430/321

(57) ABSTRACT

An optical filter for a plasma display device with improved shielding angle and transmittance, and a method of manufacturing the optical filter. The optical filter includes an external light shielding layer having a plurality of first openings; and an electromagnetic wave shielding layer integrated with the external light shielding layer on one surface of the external light shielding layer, where the electromagnetic wave shielding layer has a plurality of second openings corresponding to the plurality of first openings.

### CROSS-REFERENCE TO RELATED APPLICATIONS

This application claims priority to and the benefit of Korean Patent Application No. 10-2008-0126376, filed on Dec. 12, 2008, in the Korean Intellectual Property Office, the entire content of which is incorporated herein by reference.

### BACKGROUND OF THE INVENTION

1. Field of the Invention

An aspect of the present invention relates to an optical filter, and more particularly, to an optical filter for a plasma display device, and a method of manufacturing the optical filter.

2. Description of Related Art

A plasma display panel (PDP) is a display device which displays images by generating plasma in a discharge space between two sheets of glass substrates facing each other and exciting phosphors with the generated plasma to emit light.

However, in a PDP, electromagnetic waves are generated by plasma emission and operations of a driving circuit, and near infrared light is generated by discharge of an inert gas in the PDP. Therefore, color purity characteristics of the PDP are degraded. Further, the electromagnetic waves and near infrared light, generated in the PDP, are harmful to humans and induce malfunction of precision devices. Therefore, in a conventional PDP, an optical filter is used to shield electromagnetic waves and near infrared light, to reduce reflection of external light incident onto a visible surface of the PDP and to improve color purity.

Conventionally, an optical filter is manufactured by laminating an electromagnetic wave shielding film having a conductive film or metal mesh formed on a transparent glass or plastic substrate, and an external light shielding film.

However, the conventional optical filter is manufactured to have an electromagnetic wave shielding structure, a near infrared shielding structure and an external light shielding structure, by using at least two sheets of transparent material. Therefore, manufacturing process of a conventional optical filter is complicated and its manufacturing cost is high due to a process of laminating the respective functional layers, and the like.

And when the electromagnetic wave shielding film and the external light shielding film are laminated together, it is very difficult to align the patterns of the two functional films to each other. Accordingly, in most conventional optical filters, patterns of the two functional films cross with (i.e., not completely aligned) each other, and therefore, transmittance of light emitted from the PDP is decreased.

### SUMMARY OF THE INVENTION

Accordingly, embodiments of the present invention provide an optical filter wherein an external light shielding layer and an electromagnetic wave shielding layer are integrally formed as a single sheet, so that the pitch between barriers of the external light shielding layers is increased, thereby improving transmittance.

Embodiments of the present invention also provide a method capable of easily manufacturing the aforementioned optical filter.

According to an aspect of an embodiment of the present invention, there is provided an optical filter including an external light shielding layer having a plurality of first openings; and an electromagnetic wave shielding layer integrated with the external light shielding layer on one surface of the external light shielding layer, the electromagnetic wave shielding layer having a plurality of second openings corresponding to the plurality of first openings.

The optical filter may further include a tempered glass on the other surface of the external light shielding layer or one surface of the electromagnetic wave shielding layer.

The first and second openings may be filled with air. The optical filter may further include a transparent layer filling the first and second openings and having a refractive index of 1 to 1.5.

When the first openings have a rectangular shape, a width T of each of the first openings may satisfy Equation 1.

The thickness of the external light shielding layer may be about 20 to 500 μm. When the first openings have a rectangular shape, the pitch of the first openings in a lateral direction substantially perpendicular to the width direction may be about 50 to 1000 μm, and the pitch of the first openings in the width direction may be about 10 to 200 μm. The width of a barrier of the external light shielding layer surrounding the first openings may be about 5 to 50 μm.

The optical filter may further include an anti-reflection layer on one surface of the tempered glass.

The external light shielding layer may include a black coloring matter added to at least one material selected from the group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate, triacetate cellulose (TAC) and cellulose acetate propionate (CAP).

The conductive layer may include at least any one material of copper (Cu), silver (Ag), aluminum (Al), nickel (Ni), platinum (Au) and a combination thereof.

According to another embodiment of the present invention, there is provided a method of manufacturing an optical filter. The method includes forming a sheet of black material as an external light shielding layer; forming a conductive layer as an electromagnetic wave shielding layer on one surface of the sheet of black material; and forming a plurality of first openings in the sheet of black material and forming a plurality of second openings in the conductive layer to correspond to the plurality of first openings.

The forming of the first and second openings may include patterning the conductive layer through a photolithography process utilizing a photoresist and patterning the sheet of black material utilizing the patterned conductive layer as an etch protection layer.

When the first openings have a rectangular shape, a width T of each of the first openings may satisfy Equation 1. The thickness of the external light shielding layer may be about 20 to 500 μm. When the first openings have a rectangular shape, the pitch of the first openings in a lateral direction perpendicular to the width direction may be about 50 to 1000 μm, and the pitch of the first openings in the width direction may be about 10 to 200 μm. The width of a barrier of the external light shielding layer surrounding the first openings may be about 5 to 50 μm.

According to the embodiments of the present invention, a black material for shielding external light and a conductive layer for shielding electromagnetic waves are integrally formed in a single sheet, thereby providing an optical filter in which the pitch of the black material serving as an external light shielding layer is increased, and light transmittance is improved. Further, air or a transparent material having low permittivity fills the openings of the sheet of black material and the conductive layer, thereby minimizing loss of a shielding angle caused by refraction of external light incident onto the optical filter. Accordingly, transmittance of internal light generated and radiated from a plasma display device can be increased, and bright room contrast of the plasma display device can be improved.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 is a schematic drawing illustrating a front view of an optical filter according to an embodiment of the present invention.

FIG. 2 is a schematic drawing illustrating a cross-sectional view of the optical filter taken along the line I-I′ of FIG. 1.

FIG. 3 is a schematic drawing illustrating a cross-sectional view showing a modification of the optical filter according to an embodiment of the present invention.

FIG. 4 is a schematic drawing illustrating an enlarged cross-sectional view of a portion of an optical filter according to a comparative example.

FIG. 5 is a schematic drawing illustrating an enlarged cross-sectional view of a portion of an optical filter according to an embodiment of the present invention.

FIG. 6 is a schematic drawing illustrating a cross-sectional view showing another modification of the optical filter according to an embodiment of the present invention.

FIGS. 7A, 7B and 7C are schematic perspective views drawings illustrating a method of manufacturing an optical filter according to an embodiment of the present invention.

### DETAILED DESCRIPTION OF EXEMPLARY EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the another element or be indirectly on the another element with one or more intervening elements interposed therebetween. Also, when an element is referred to as being “connected to” another element, it can be directly connected to the another element or be indirectly connected to the another element with one or more intervening elements interposed therebetween. Hereinafter, like reference numerals refer to like elements.

In the following description, the term “transparent” has not only a meaning of perfect transparency but also a meaning of light transmittance to a certain degree, which is typically considered as transparent in the art. In the drawings, the thicknesses or sizes of layers are exaggerated for clarity.

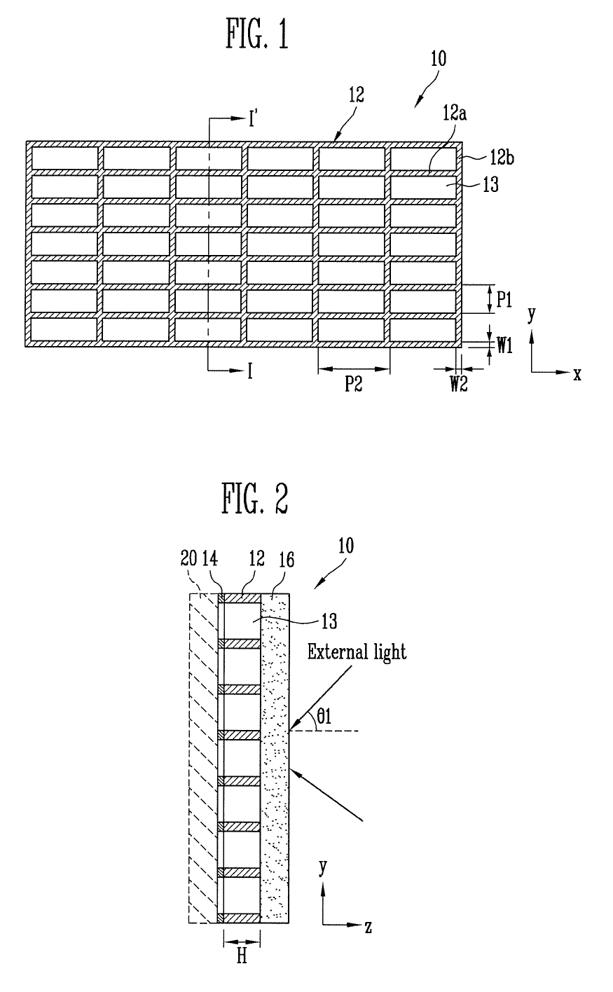

FIG. 1 is a schematic drawing illustrating a front view of an optical filter according to an embodiment of the present invention. FIG. 2 is a schematic drawing illustrating a cross-sectional view of the optical filter according to the embodiment of the present invention. FIG. 2 illustrates a section of the optical filter taken along the line I-I′ of FIG. 1.

Referring to FIGS. 1 and 2, the optical filter 10 includes an external light shielding layer 12, an electromagnetic wave shielding layer 14 and a tempered glass 16. In the optical filter 10 according to the embodiment of the present invention, the external light shielding layer 12 is patterned into a predetermined pattern, and the electromagnetic wave shielding layer 14 is patterned in the same pattern as that of the external light shielding layer 12.

That is, in the optical filter 10 according to the embodiment of the present invention, the patterns of the external light shielding layer 12 and the electromagnetic wave shielding layer 14 substantially correspond to each other so as to solve a problem of the conventional optical filter in which patterns of an external light shielding layer and an electromagnetic wave shielding layer do not correspond to each other. To this end, the external light shielding layer 12 and the electromagnetic wave shielding layer 14 are integrally formed in a single sheet.

The respective components will be described in detail. The external light shielding layer 12 functions to shield light incident onto one surface of the external light shielding layer 12 with a specific angle or more. The external light shielding layer 12 includes first barriers 12a extending in the x-axis direction (row direction or lateral direction of a rectangle), second barriers 12b extending in the y-axis direction (column direction or longitudinal direction of the rectangle), and a plurality of openings 13 defined by the barriers 12a and 12b. The external light shielding function is performed by portions of the first barriers 12a extending in the row direction. In this embodiment, the external light shielding layer 12 is formed in a mesh pattern having a black-based color. The black-based color has not only a meaning of perfect black but also a meaning of light transmittance to a certain degree, which is typically considered as black in the art.

The thickness H of the external light shielding layer 12, the width W of each of the barriers and the pitch P between the barriers extending in the y-axis direction are appropriately controlled to shield light incident from the outside with a slope greater than a specific angle with respect to the x-axis direction. If such conditions are not met, external light shielding efficiency is considerably decreased. As illustrated in FIG. 2, when external light shielding is performed by the optical filter 10, light incident on the optical filter 10 with an angle θ1 or larger is not incident onto a display device shielded by the optical filter 10.

The electromagnetic wave shielding layer 14 shields electromagnetic waves transferred from one surface to the other surfaces thereof. The electromagnetic wave shielding layer 14 has a mesh pattern having rectangular openings with the same size and shape as those of the external light shielding layer 12. Here, the electromagnetic shielding function is performed by portions of the mesh pattern extending in row and column directions.

The electromagnetic wave shielding layer 14 is formed of a conductive material. All conductive materials currently used for shielding electromagnetic waves may be used as the conductive material. For example, the conductive material includes at least one of copper (Cu), silver (Ag), aluminum (Al), nickel (Ni), platinum (Au) and a combination thereof.

The tempered glass 16 is disposed as an uppermost or outermost layer of the optical filter 10 so as to protect the display device from impacts or scratches generated by various types of external forces. When the external light shielding layer 12 and the electromagnetic wave shielding layer 14 are integrally formed as a sheet that is attached on a front substrate 20 of the display device, the tempered glass 16 functions to allow air to be filling the openings 13 interposed between the front substrate 20 and the tempered glass 16.

The tempered glass 16 may be disposed opposite to the electromagnetic wave shielding layer 14 with the external light shielding layer 12 interposed therebetween. Alternatively, the tempered glass 16 may be disposed opposite to the external light shielding layer 12 with the electromagnetic wave shielding layer 14 interposed therebetween.

The tempered glass 16 may be produced by performing a thermal treatment with respect to a plate glass and rapidly cooling the plate glass, by heating a normal glass at over a softening temperature, deforming the heated glass into a desired shape and rapidly cooling the deformed glass with compressed air, or by performing a chemical treatment. For example, the tempered glass 16 may be produced by depositing glass into a potassium nitrate solution at a proper temperature to induce ion exchange with the glass in a salt tank and allowing compression stress to be generated on the surface of the glass by the ion exchange.

In the external light shielding layer 12 and the electromagnetic wave shielding layer 14, the width W1 or W2 of each of the barriers or pattern of the external light shielding layer 12 and the electromagnetic wave shielding layer 14 in the y-axis or x-axis direction is formed in a range of about 5 to 50 μm according to an embodiment of present invention, and formed in a range of about 5 to 30 μm according to another embodiment of present invention. If the width (W1 or W2) is below 5 μm, transmittance is significantly lowered. If the width (W1 or W2) exceeds 30 μm, moiré pattern may be generated. Particularly, if the width (W1 or W2) exceeds 50 μm, moiré pattern may be easily generated.

In the external light shielding layer 12 and the electromagnetic wave shielding layer 14, a first pitch P1 in the y-axis direction is about 10 to 200 μm, and a second pitch P2 in the x-axis direction is about 50 to 1000 μm. The range of the first pitch P1 provides a desired external light shielding effect, which will be described in detail below. The range of the second pitch P2 provides a desired electromagnetic shielding effect when the external light shielding layer 12 and the electromagnetic wave shielding layer 14 are integrally formed having the second pitch P2 and the first pitch P1. Therefore, if the first pitch P1 is out of the above-described range, the external light shielding effect is lowered, and accordingly, transmittance or bright room contrast may be lowered. If the second pitch P2 is out of the above-described range, the electromagnetic wave shielding effect is lowered, and accordingly, transmittance may be lowered. In the instant specification, the term “pitch” refers to a periodic interval between adjacent barriers of an external light shielding layer, an electromagnetic wave shielding layer or a black material for forming the external light shielding layer.

The thickness H of the external light shielding layer 12 is in the range of about 20 to 500 μm according to an embodiment of the present invention, and in the range of about 20 to 300 μm according to another embodiment of the present invention. If the thickness H of the external light shielding layer 12 is below 20 μm, which is too thin, or if the thickness H of the external light shielding layer 12 exceeds 500 μm, which is too thick, it is difficult to implement the barriers 12a and 12b themselves.

In the embodiment of FIGS. 1 and 2, the openings 13 of the external light shielding layer 12 and the electromagnetic wave shielding layer 14 are not filled with a transparent material but filled with air. In the conventional optical filter, incident light is refracted by the transparent material, and hence, the pitch of an external light shielding layer of the conventional optical filter is reduced. Consequently, transmittance of a display device is lowered due to the reduced pitch.

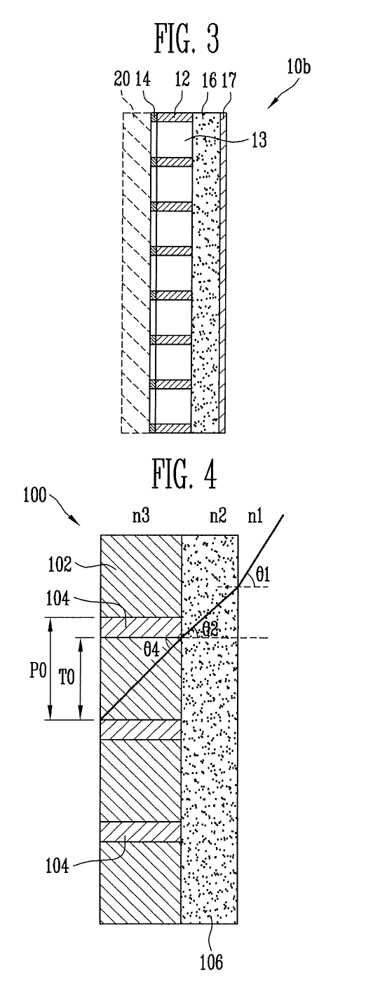

As shown in FIG. 3, an optical filter 10b according to an embodiment of the present invention may further include an anti-reflection layer 17 in addition to the external light shielding layer 12, the electromagnetic wave shielding layer 14 and the tempered glass 16. The anti-reflection layer 17 is formed on one surface of the tempered glass 16 and performs an anti-reflective (AR) function and/or low-reflective (LR) function(s) of preventing surface reflection of a screen using optical interference.

To provide the AR function, the anti-reflection layer 17 may be formed by using a dry coating method of laminating an inorganic derivative material through deposition or sputtering, or by using a wet coating method of coating an organic material. Here, the anti-reflection layer 17 may be formed of a plurality of layers having different refractive indices. Alternatively, to provide the LR function, the anti-reflection layer 17 may be formed by coating a material having a low refractive index as a single layer. Here, the anti-reflection layer 17 performing the LR function may have a reflectance of about 1% according to an embodiment of the present invention. The material of the anti-reflection layer 17 may include an organic material such as fluorine-based resin, or an inorganic material such as SiO₂ or ITO. The anti-reflection layer 17 may be coated on the one surface of the tempered glass 16 or may be attached on the one surface of the tempered glass 16 as a separate film.

FIG. 4 is an enlarged cross-sectional view of a portion of an optical filter according to a comparative example. FIG. 5 is an enlarged cross-sectional view of a portion of an optical filter according to an embodiment of the present invention.

As shown in FIG. 4, an optical filter 100 according to the comparative example includes a transparent glass 106, a transparent layer 102 formed on one surface of the transparent glass 106, and an external light shielding layer 104 buried in the transparent layer 102 on the one surface of the transparent glass 106. Typically, the transparent layer 102 is made of a transparent polymer substance, and the external light shielding layer 104 is made of a black substance such as carbon black. The transparent layer 102 typically has a refractive index of 1.5 to 1.6.

The optical filter 100 according to the comparative example is typically manufactured by coating a transparent polymer substance on the transparent glass 106, forming grooves in the coated transparent polymer substance and filling carbon black into the grooves.

When assuming that the refractive index of air is a first refractive index n1, the refractive index of the transparent glass 106 is a second refractive index n2, and the refractive index of the transparent polymer substance for forming the transparent layer 102 is a fourth refractive index n4, the second refractive index n2 of the transparent glass 106 is substantially similar to the fourth refractive index n4 of the transparent polymer substance, i.e., θ2≈θ4. Accordingly, when external light is incident onto the optical filter 100 with a first angle θ1, the external light passes from the transparent glass 106 to the transparent layer 102 with almost no refraction due to the second and fourth refractive indices n2 and n4 being substantially similar to each other. As such, in the optical filter 100, the pitch P0 between barriers of the external light shielding layer 104 is formed narrow so that the external light is effectively shielded. Therefore, luminance of a plasma display device is lowered due to a decreased area through which light emitted from a plasma display device is transmitted.

On the other hand, in the optical filter 10 according to the embodiment of the present invention, when external light is incident onto the optical filter 10 with a first angle θ1, the external light is refracted with a second angle θ2 at a boundary of the tempered glass 16 and again refracted with the first angle θ1 by the air filling the openings 13 while advancing into the openings 13, as shown in FIG. 5. Here, the first refractive index n1 of external air is equal to a third refractive index n3 of the air filling the openings 13. Therefore, the advancing path of the external light refracted by the tempered glass 16 having the second refractive index n2 is restored by the air layer filling the openings 13 having the third refractive index n3. Accordingly, in the optical filter 10 shown in FIG. 5, the pitch P1 between the barriers of the external light shielding layer 12 can be increased while external light is appropriately shielded.

As described above, in the optical filter 10 according to the embodiment of the present invention, the pitch P1 between the barriers in the column direction of the external light shielding layer 12 is greater than the pitch P0 between the barriers in the column direction of the optical filter 100. That is, according to the above-described embodiment of the present invention, luminance of the plasma display device can be increased by increasing an area through which light emitted from the plasma display device is transmitted, as compared with the comparative example.

In the optical filter 10, the width of the opening 13 obtained by subtracting the width W1 of the barrier in the column direction from the pitch P1 between the barriers of the external light shielding layer 12 or the interval T between the barriers in the column direction may be determined by the following Equation 1.

Equation 1

T=H×tan [sin⁻¹((n1/n3)×sin θ1)] (1)

Here, H denotes a thickness of a black material used as the external light shielding layer 12, n1 denotes a refractive index of air, n3 denotes a refractive index of a substance filling the openings 13, and θ1 denotes an incident angle of external light incident onto the tempered glass 16.

In Equation 1, n1 is 1 equal to the refractive index of air, and n3 is dependent upon the refractive index of the substance filling the openings 13. Accordingly, when the openings 13 in the external light shielding layer 12 is filled with air, light refracted by the tempered glass is restored based on the refractive index of the air in the openings 13, and hence, it is unnecessary to reduce the interval T between the barriers.

If the interval T between the barriers is determined based on Equation 1, light incident with the specific angle θ1 or more can be perfectly shielded. However, if the interval T between the barriers is smaller than a value determined by Equation 1, transmittance is lowered, and the incident angle of light to be shielded is decreased. If the interval T between the barriers is greater than a value determined by Equation 1, light incident with the specific angle θ1 is not shielded and incident upon the display device. In this case, transmittance is increased, but reflection luminance is increased and therefore, bright room contrast of the display device is decreased.

Hereinafter, the optical filter 10 according to the embodiment of the present invention and the optical filter 100 according to the comparative example will be described in detail in conjunction with a comparative experimental example.

First, in the optical filter 10 according to the embodiment of the present invention, the tempered glass 16 having a refractive index of 1.55 is disposed as an outermost layer, and the external light shielding layer 12 and the electromagnetic wave shielding layer 14 are disposed on one surface of the tempered glass 16. The thickness H of the external light shielding layer 12 is 84 μm, and the width W1 of each barrier is 30 μm. Here, since the electromagnetic wave shielding layer 14 has a thickness smaller than the thickness H of the external light shielding layer 12, it is not shown in FIG. 5. The thickness H of the external light shielding layer 12 may include the thickness of the electromagnetic wave shielding layer 14 and the thickness of the external light shielding layer 12.

Subsequently, the openings 13 of the external light shielding layer 12 are filled with air while the optical filter 10 is attached on a front substrate of a panel.

By way of example, three optical filters were manufactured by varying the pitch P1 of the external light shielding layer 12 depending on angles of external incident light. Shielding angles, refraction angles and transmittances were measured from the respective three optical filters. The measured results are shown in Table 1.

TABLE 1

| | Incident angle | Pitch | θ2 | θ3 | |
|---|---|---|---|---|---|
| | [degree] | [μm] | [degree] | [degree] | Transmittance |
| Embodiment | 45 | 114 | 27.14 | 45 | 74% |
| | 55 | 150 | 31.91 | 55 | 80% |
| | 65 | 210 | 35.78 | 65 | 86% |

On the other hand, in the optical filter 100 according to the comparative example, the tempered glass 106 having a refractive index of 1.55 was disposed as an outermost layer, and the external light shielding layer 104 was disposed on one surface of the tempered glass 106. In the comparative example, the thickness of the external light shielding layer 104 was 84 μm and the width of each barrier was 30 μm. The stripe patterns of the external light shielding layer 104 formed in a mesh pattern is filled with a transparent polymer substance. The optical filter 100 was attached on a front substrate of another panel.

By way of example, three optical filters were manufactured with different pitches between the barriers of the external light shielding layer 104 according to the angles of external incident light. Shielding angles, refraction angles and transmittances were measured from the respective three optical filters. The measured results are shown in Table 2.

TABLE 2

| | Incident angle | Pitch | θ2 | Θ4 | |
|---|---|---|---|---|---|
| | [degree] | [μm] | [degree] | [degree] | Transmittance |
| Comparative | 45 | 75 | 27.19 | 28.18 | 60% |
| Example | 55 | 85 | 32.01 | 33.22 | 65% |
| | 65 | 94 | 35.91 | 37.3 | 68% |

In Tables 1 and 2, the second refraction angle θ2 denotes a refraction angle of light refracted by a tempered glass. The third refraction angle θ3 denotes a refraction angle of light refracted by the air filling the openings of the external light shielding layer according to the embodiment of the present invention, and the fourth refraction angle θ4 denotes a refraction angle of light refracted by the transparent polymer substance filling the spaces between the barriers of the external light shielding layer according to the comparative example.

As shown in Tables 1 and 2, the optical filter 100 according to the comparative example will be compared with the optical filter 10 according to the embodiment of the present invention. In the optical filter 100 according to the comparative example, it can be seen that the shielding angle of external light incident on the optical filter 100 with the same angle as that in the optical filter 10 is not restored by the refractive index of the transparent polymer substance, and therefore, transmittance is relatively decreased.

Hereinafter, the optical filter 10 according to the embodiment of the present invention and the optical filter 100 according to the comparative example will be described in detail in conjunction with another comparative example.

Three exemplary optical filters having the structure of the optical filter 10 are manufactured by filling air between the barriers of each of the external light shielding layers, respectively, and transmittance variations depending on thickness variations of the external light shielding layers were measured with respect to the respective three optical filters. Here, the incident angle of light and the width of each of the barriers were fixed to predetermined values.

In the optical filter 100 according to the comparative example, a transparent polymer substance 102 having a refractive index of 1.5 fills the spaces between the barriers of the external light shielding layer 104. Three exemplary optical filters having the same structure as that of the optical filter 100 were manufactured according to embodiments of the present invention, and transmittance variations depending on thickness variations of the external light shielding layers 104 were measured with respect to the respective three optical filters. The measured results are shown in Tables 3 and 4.

TABLE 3

| | Thickness of | Incident | Interval | |
|---|---|---|---|---|
| | external light | angle | between | Transmit- |
| | shielding layer [μm] | [degree] | barriers [μm] | tance |
| Embodiment | 30 | 50 | 35.75 | 54% |
| | 60 | 50 | 71.51 | 70% |
| | 90 | 50 | 107.26 | 78% |

TABLE 4

| | Thickness of | Incident | Interval | |
|---|---|---|---|---|
| | external light | angle | between | Transmit- |
| | shielding layer [μm] | [degree] | barriers [μm] | tance |
| Comparative | 30 | 50 | 17.82 | 37% |
| Example | 60 | 50 | 35.64 | 54% |
| | 90 | 50 | 53.46 | 64% |

As shown in Tables 3 and 4, the optical filters according to the comparative example will be compared with the optical filters according to the embodiments of the present invention. Although the external light shielding layers of the optical filters according to the comparative example have the same thickness as those of the optical filters according to the embodiments of the present invention, the interval between the barriers or stripe patterns is narrower due to the refractive index of the transparent polymer substance filling the spaces between the barriers of each of the external light shielding layers, and therefore, transmittance is relatively decreased.

As described above, according to the embodiment of the present invention, transmittance of an optical filter can be increased by increasing an area of the optical filter through which internal light radiated from the display device is transmitted. Further, the bright room contrast of the plasma display device can be improved.

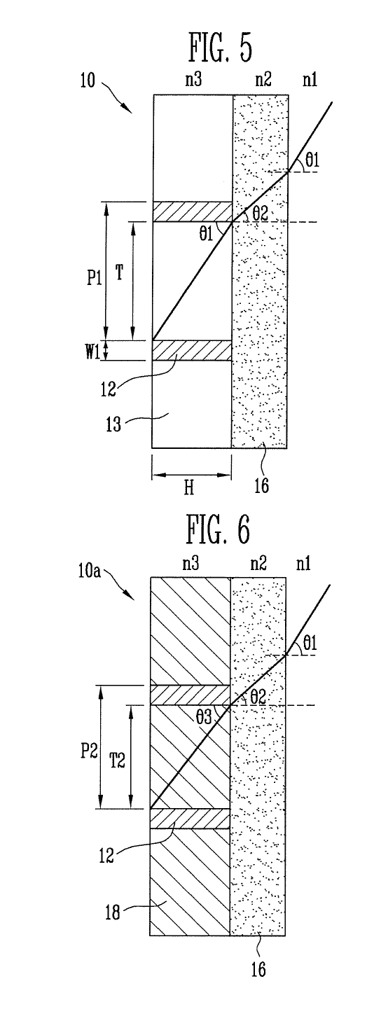

As shown in FIG. 6, in an optical filter 10a according to another embodiment of the present invention, air is not in the openings 13 between the barriers of the external light shielding layer 12, but a transparent layer 18 is formed in each of the openings 13. Here, the transparent layer 18 is made of a transparent polymer substance having a refractive index of 1 to 1.5.

In this embodiment, external light incident onto the optical filter 10a is incident onto the tempered glass 16 of the optical filter 10a with a first angle θ1, refracted with a second angle θ2 at a boundary of the tempered glass 16 and then advances into the transparent layer 18. Here, the refractive index of the transparent layer 18 is smaller than that of the transparent layer 102 of FIG. 4. Therefore, the external light incident onto the optical filter 10a is refracted at the boundary between the tempered glass 16 and the transparent layer 18 with a third refraction angle θ83 greater than the fourth refraction angle θ4 of FIG. 4. That is, an interval T2 between the barriers in the transparent layer 18 of the optical filter 10a may be formed greater than the interval T0 between the barriers in the transparent layer 102 of the optical filter 100.

In other words, in the optical filter 10a, external light refracted by the tempered glass 16 is restored with a relatively greater angle than that in the optical filter 100. Accordingly, the pitch P2 between the barriers of the external light shielding layer 12 in the optical filter 10a can be formed greater than the pitch P0 between the barriers of the external light shielding layer 104 in the optical filter 100.

As described above, in the optical filter 10a, the external light shielding layer 12 and the electromagnetic wave shielding layer are integrally formed to have the same pattern, so that external light can be shielded in a way similar to the optical filter 10, and transmittance of light radiated from the interior side of the optical filter 10a can be increased more than that in the optical filter 100.

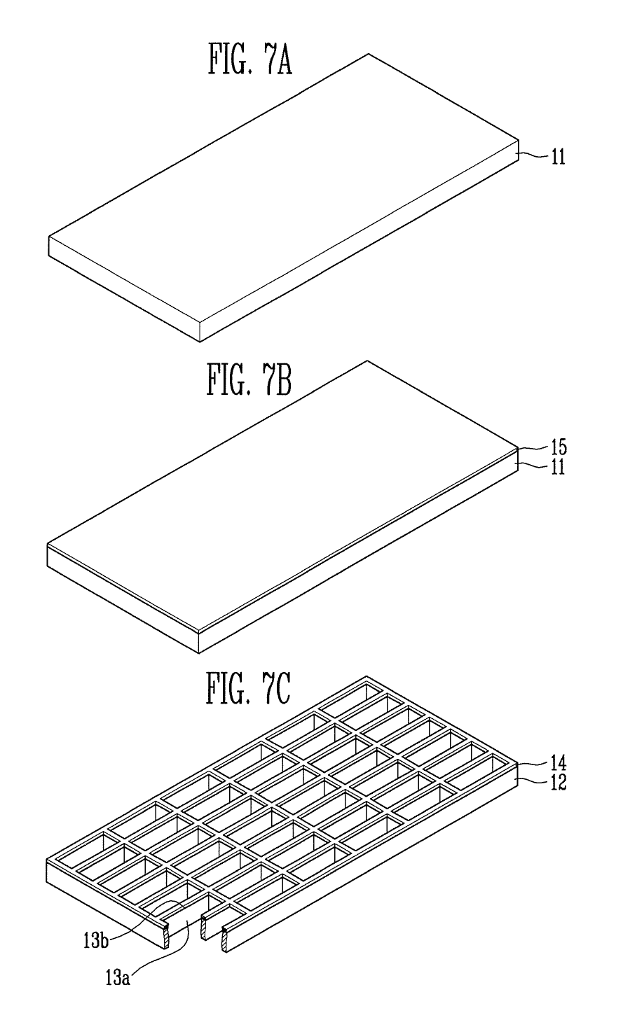

FIGS. 7A to 7C are schematic perspective view drawings illustrating a method of manufacturing an optical filter according to an embodiment of the present invention. In FIG. 7C, a portion of the optical filter is cut away.

As shown in FIG. 7A, a black material 11 is prepared to be used as an external light shielding layer. The black material 11 has a black color capable of effectively shielding and absorbing external light.

In one embodiment, the black material 11 is prepared by adding a black coloring matter to any one material selected from the group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate, triacetate cellulose (TAC) and cellulose acetate propionate (CAP). In one embodiment, the thickness of the black material 11 is about 20 to 500 μm. If the thickness of the black material 11 is too thin, the black material is easily damaged during the manufacturing process. If the thickness of the black material 11 is too thick, the thickness of the optical filter is unnecessarily increased, and it is difficult to perform patterning.

According to an embodiment of the present invention, the black material 11 is formed as follows: a film having a thickness of 200 μm is formed by melting a PET pellet containing a predetermined amount of black coloring matter at a temperature of 290 to 300° C. and compressing the melted pellet using an extruder. Then, the film is heated and biaxially stretched to a thickness of 100 μm.

As shown in FIG. 7B, a conductive layer 15 used as an electromagnetic wave shielding layer is formed on one surface of the black material 11. The conductive layer 15 is made of, for example, a metal, a metal oxide or an alloy, which has excellent conductivity.

The conductive layer 15 may be formed by performing a layer forming process such as sputtering or printing, or may be formed by attaching a sheet-shaped copper (Cu) mesh on the one surface of the back material 11 using an adhesive or gluing agent. In the embodiment of FIG. 7B, the conductive layer 15 is formed by attaching the sheet-shaped copper (Cu) mesh on the one surface of the black material 11 using an adhesive (not shown).

To obtain an excellent electromagnetic interference (EMI) shielding effect, the resistance per unit area, i.e., the surface resistance of the conductive layer 15 is 0.04 to 0.05 Ω/sq. according to an embodiment of the present invention. Although the optimal thickness of the conductive layer 15 slightly varies depending on the material of the conductive layer 15, the thickness of the conductive layer 15 is about 10 to 12 μm according to an embodiment of the present invention. If the thickness of the conductive layer 15 is thinner than 10 μm, the conductive layer 15 may be easily damaged during an operation. If the thickness of the conductive layer 15 is thicker than 12 μm, the thickness of the optical filter may be unnecessarily thick.

As shown in FIG. 7C, a plurality of second openings 13b are formed in the conductive layer 15, and a plurality of first openings 13a are formed in the black material 11. For example, the conductive layer 15 may be patterned through a photolithography process using a photoresist, and the black material 11 may be patterned through a dry etching process using the patterned conductive layer 15 as an etch protection layer. It will be apparent that the conductive layer 15 and the black material 11 may be simultaneously or individually patterned through a dry or wet etching process generally known in the art.

Through the aforementioned method, the optical filter can be manufactured, which includes an external light shielding layer 12 having the plurality of first openings 13a, and an electromagnetic wave shielding layer 14 formed on one surface of the external light shielding layer 12 having the plurality of second openings 13b corresponding to the plurality of first openings 13a.

According to the aforementioned embodiments of the present invention, an external light shielding layer and an electromagnetic wave shielding layer in an optical filter are integrally formed as a sheet having a mesh pattern, and/or openings in the sheet having the mesh pattern are filled with air or a transparent material having a low permittivity close to the permittivity of air, thereby increasing the pitch between the barriers of the external light shielding layer and minimizing loss of a shielding angle due to the refractive index of a substance filling the openings. Further, there can be provided a high-efficiency and high-quality plasma display device having low external light reflection and high transmittance.

Meanwhile, in the aforementioned embodiments of the present invention, a tempered glass is disposed on one surface of the sheet in which the external light shielding layer and the electromagnetic wave shielding layer are integrally formed in a mesh pattern. However, the present invention is not limited thereto. That is, a transparent material having a predetermined strength may be used rather than the tempered glass. The transparent material may include PET and the like.

While the present invention has been described in connection with certain exemplary embodiments, it is to be understood that the present invention is not limited to the disclosed embodiments, but, on the contrary, is intended to cover various modifications and equivalent arrangements included within the spirit and scope of the appended claims, and equivalents thereof.

What is claimed is:

1. An optical filter comprising:
an external light shielding layer having a plurality of first openings; and
an electromagnetic wave shielding layer integrated with the external light shielding layer on one surface of the external light shielding layer, the electromagnetic wave shielding layer having a plurality of second openings corresponding to the plurality of first openings.

2. The optical filter of claim 1, further comprising a tempered glass on the other surface of the external light shielding layer or one surface of the electromagnetic wave shielding layer.

3. The optical filter of claim 2, wherein the first and second openings are filled with air.

4. The optical filter of claim 2, further comprising a transparent layer filling the first and second openings and having a refractive index of 1 to 1.5.

5. The optical filter of claim 2, wherein, when the first openings have a rectangular shape, a width T of each of the first openings satisfies the following equation:
T=H×tan [sin⁻¹((n1/n3)×sin θ1)],
wherein H denotes the thickness of the external light shielding layer, n1 denotes a refractive index of air, n3 denotes a refractive index of a substance filling the first openings, and θ1 denotes an incident angle of external light incident onto the tempered glass.

6. The optical filter of claim 5, wherein the pitch of the first openings in a lateral direction substantially perpendicular to the width direction is about 50 to 1000 μm, and the pitch of the first openings in the width direction is about 10 to 200 μm.

7. The optical filter of claim 6, wherein the thickness of the external light shielding layer is about 20 to 500 μm.

8. The optical filter of claim 7, wherein the width of a barrier of the external light shielding layer surrounding the first openings is about 5 to 50 μm.

9. The optical filter of claim 2, further comprising an anti-reflection layer on one surface of the tempered glass.

10. The optical filter of claim 1, wherein the external light shielding layer comprises at least one material selected from the group consisting of polyethersulphone (PES), polyacrylate (PAR), polyetherimide (PEI), polyethylene naphthalate (PEN), polyethylene terephthalate (PET), polyphenylene sulfide (PPS), polyallylate, polyimide, polycarbonate, triacetate cellulose (TAC) and cellulose acetate propionate (CAP), and a black coloring matter added to the at least one material.

11. A method of manufacturing an optical filter, the method comprising:
forming a sheet of black material as an external light shielding layer;
forming a conductive layer as an electromagnetic wave shielding layer on one surface of the sheet of black material; and
forming a plurality of first openings in the sheet of black material and forming a plurality of second openings in the conductive layer to correspond to the plurality of first openings.

12. The method of claim 11, wherein the forming of the first and second openings comprises patterning the conductive layer through a photolithography process utilizing a photoresist and patterning the sheet of black material utilizing the patterned conductive layer as an etch protection layer.

13. The method of claim 11, further comprising attaching a tempered glass on the other surface of the sheet of black material or on one surface of the conductive layer.

14. The method of claim 13, further comprising filling the first and second openings with air.

15. The method of claim 13, further comprising filling the first and second openings with a transparent material having a refractive index of 1 to 1.5.

16. The method of claim 13, wherein:
the first openings have a rectangular shape; and
a width T of each of the first openings satisfies the following equation:
T=H×tan [sin⁻¹((n1/n3)×sin θ1)],
wherein H denotes the thickness of the external light shielding layer, n1 denotes a refractive index of air, n3 denotes a refractive index of a substance filling the first openings, and θ1 denotes an incident angle of external light incident onto the tempered glass.

17. The method of claim 16, wherein the pitch of the first openings in a lateral direction substantially perpendicular to the width direction is about 50 to 1000 μm, and the pitch of the first openings in the width direction is about 10 to 200 μm.

18. The method of claim 17, wherein the thickness of the external light shielding layer is about 20 to 500 μm.

19. The method of claim 18, wherein the width of a barrier of the external light shielding layer, surrounding the first openings, is about 5 to 50 μm.

20. The method of claim 11, further comprising forming an anti-reflection layer on one surface of the tempered glass.
